(19) United States
(12) Patent Application Publication
(10) Pub. No.: US 2025/0357742 A1
(43) Pub. Date: Nov. 20, 2025

(54) SEMICONDUCTOR DEVICE

(71) Applicant: FUJI ELECTRIC CO., LTD., Kawasaki-shi (JP)

(72) Inventor: Kei MINAGAWA, Matsumoto-city (JP)

(73) Assignee: FUJI ELECTRIC CO., LTD., Kawasaki-shi (JP)

(21) Appl. No.: 19/088,352

(22) Filed: Mar. 24, 2025

(30) Foreign Application Priority Data
May 14, 2024 (JP) 2024-078595

(51) Int. Cl. H02H 3/08; H02H 1/00

(52) U.S. Cl. CPC H02H 3/08; H02H 1/0007

(57) ABSTRACT

There is provided a semiconductor device capable of preventing a deterioration of a function of protecting a switching element to be protected, even when the temperatures of the switching element and a control circuit controlling the switching element are different from each other. A semiconductor device includes: a semiconductor element having a switching element, a temperature detection section, and a current detection section; and a control circuit configured to control the semiconductor element, in which the control circuit has a signal generation section configured to generate a temperature variable signal varying according to a detection temperature detected by the temperature detection section using a temperature detection signal having information on the detection temperature, and an overcurrent detection section configured to detect that a current flowing into the switching element is an overcurrent using a current detection signal having information on a detection current detected by the current detection section and the temperature variable signal output from the signal generation section.

### CROSS-REFERENCE TO RELATED APPLICATION

This application claims benefit of priority under 35 USC 119 based on Japanese Patent Application No. 2024-078595 filed on May 14, 2024, the entire contents of which are incorporated by reference herein.

### TECHNICAL FIELD

The present invention relates to a semiconductor device including a switching element.

### BACKGROUND ART

PTL 1 discloses a technology: “With the aim of providing a semiconductor device and an overcurrent protection function of the semiconductor device, in which the accuracy of a switching element protection function is increased, the semiconductor device includes: a chip temperature detection diode of a switching element; a control circuit temperature detection diode arranged in a control circuit controlling the switching element; and an overcurrent reference voltage collection circuit comparing detection potentials of both the detection diodes, correcting an overcurrent reference voltage generated in an overcurrent reference voltage circuit, and outputting the overcurrent reference voltage after the correction”.

### CITATION LIST

### Patent Literature

PTL 1: JP 2021-150820 A

### SUMMARY OF INVENTION

### Technical Problem

The semiconductor device including the function of protecting the switching element from an overcurrent has such a problem that the function of protecting the switching element deteriorates when the temperatures of the switching element to be protected and the control circuit controlling the switching element are different from each other.

It is an object of the present invention to provide a semiconductor device capable of preventing the deterioration of the function of protecting the switching element to be protected, even when the temperatures of the switching element and the control circuit controlling the switching element are different from each other.

### Solution to Problem

To achieve the above-described object, a semiconductor device according to one aspect of the present invention includes: a semiconductor element having a switching element, a temperature detection section configured to detect the temperature of the switching element, and a current detection section configured to detect a current of the switching element; and a control circuit configured to control the semiconductor element, in which the control circuit has a signal generation section configured to generate a temperature variable signal varying according to a detection temperature detected by the temperature detection section using a temperature detection signal having information on the detection temperature, and an overcurrent detection section configured to detect that a current flowing into the switching element is an overcurrent using a current detection signal having information on a detection current detected by the current detection section and the temperature variable signal output from the signal generation section.

### Advantageous Effects of Invention

According to one aspect of the present invention, even when the temperatures of the switching element to be protected and the control circuit controlling the switching element are different from each other, the deterioration of the function of protecting the switching element can be prevented.

### BRIEF DESCRIPTION OF DRAWINGS

FIG. 1 is a block diagram illustrating one example of the schematic configuration of a semiconductor device according to a first embodiment of the present invention;

FIG. 2 is a view for explaining the semiconductor device according to the first embodiment of the present invention, and is a graph showing one example of the temperature characteristic of a temperature detection section detecting the temperature of a switching element;

FIG. 3 is a view schematically illustrating a cross-section of the semiconductor device according to the first embodiment of the present invention;

FIG. 4 is a view for explaining the semiconductor device according to the first embodiment of the present invention, and is a graph showing one example of the temperature characteristic of a temperature variable signal relative to the temperature of the switching element;

FIG. 5 is a view for explaining the semiconductor device according to the first embodiment of the present invention, and is a graph showing one example of the voltage level of the temperature variable signal set when the temperature of the switching element is normal temperature;

FIG. 6 is a view for explaining the semiconductor device according to the first embodiment of the present invention, and is a graph showing one example of the voltage level of the temperature variable signal set when the temperature of the switching element is a predetermined temperature higher than normal temperature;

FIG. 7 is a graph showing one example of a reference voltage for detecting an overcurrent set when the temperatures of a switching element and a control circuit are different from each other in a conventional technology as a comparative example; and

FIG. 8 is a block diagram illustrating one example of the schematic configuration of a semiconductor device according to a second embodiment of the present invention.

### DESCRIPTION OF EMBODIMENTS

Embodiments of the present invention exemplify devices or methods for embodying the technical idea of the present invention. The technical idea of the present invention does not specify the materials, shapes, structures, arrangement, and the like of constituent components to the materials, shapes, structures, arrangement, and the like described below. The technical idea of the present invention can be variously altered in the technical scope defined by the claims.

### First Embodiment

### 1-1. Configuration of Semiconductor Device

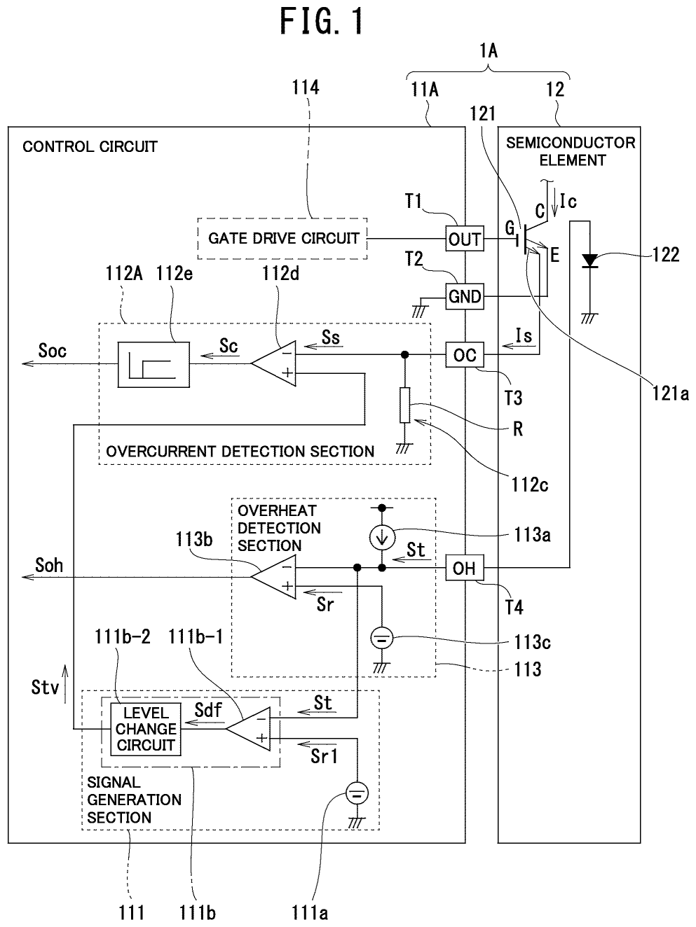

The schematic configuration of a semiconductor device according to a first embodiment of the present invention is described using FIGS. 1 to 6. The semiconductor device according to this embodiment is applicable, for example, to an intelligent power module (IPM) where a switching element and a reflux diode, and an integrated circuit for driving/protection functions of driving/protecting the switching element are integrated in a single package and other semiconductor modules. FIG. 1 is a block diagram illustrating one example of the schematic configuration of a semiconductor device 1A according to this embodiment.

As illustrated in FIG. 1, the semiconductor device 1A according to this embodiment includes a semiconductor element 12 and a control circuit 11A controlling the semiconductor element 12. The semiconductor element 12 has a switching element 121, a temperature detection section 122 detecting the temperature of the switching element 121, and a current detection section 121a detecting a current of the switching element 121. The switching element 121 contains, for example, an insulated gate bipolar transistor.

In this embodiment, the switching element is a voltage-controlled element, for example, as in the switching element 121. The switching element 121 has a collector C connected to a predetermined circuit (not illustrated) formed in the semiconductor element 12 or the like. The switching element 121 has an emitter E connected to a reference potential terminal T2 provided in the control circuit 11A. The switching element 121 has a gate G connected to a gate signal output terminal T1 provided in the control circuit 11A. The reference potential terminal T2 is connected to a reference potential part kept at the reference potential (e.g., ground potential) of the control circuit 11A. Thus, the emitter E of the switching element 121 is connected to the reference potential part via the reference potential terminal T2 and is kept at the same potential as the reference potential of the control circuit 11A.

The current detection section 121a built in the switching element 121 has an output connected to an overcurrent detection terminal T3 provided in the control circuit 11A. To the current detection section 121a, a current of, for example, about one ten-thousandth of a collector current Ic of the switching element 121 is shunted. The current detection section 121a outputs a detection current Is shunted from the collector current Ic into the control circuit 11A via an overcurrent detection terminal T3.

The temperature detection section 122 has an anode connected to a temperature detection terminal T4 provided in the control circuit 11A. The temperature detection section 122 has a cathode connected to a reference potential part kept at the reference potential of the semiconductor element 12. The temperature detection section 122 is a diode having temperature dependency, for example. Therefore, the resistivity of the temperature detection section 122 has a temperature characteristic in which the resistivity at a high temperature is lower than the resistivity at a low temperature, for example. Therefore, in the temperature detection section 122, the resistivity varies according to the temperature of the switching element 121 and a forward voltage also varies.

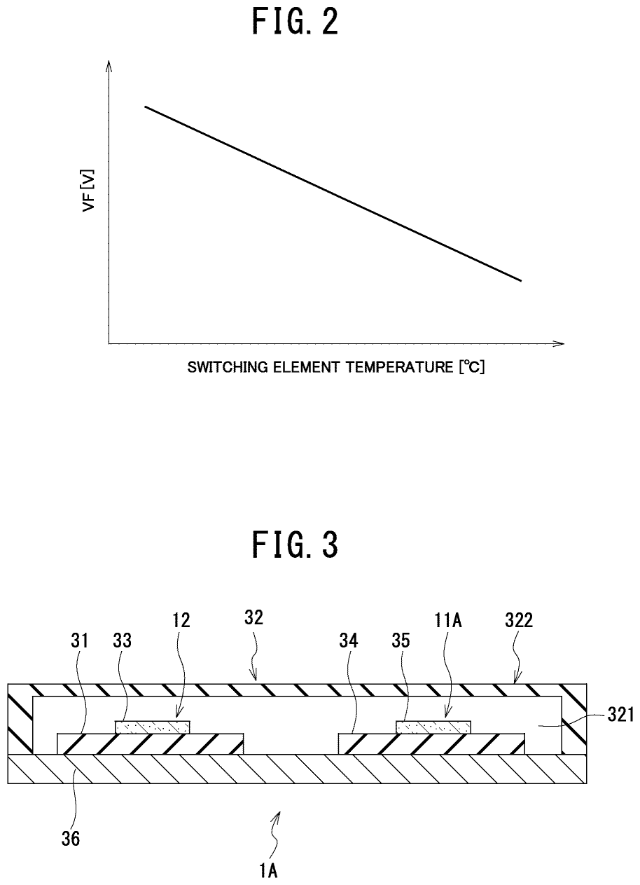

FIG. 2 is a view schematically illustrating one example of the temperature characteristic of the forward voltage of the temperature detection section 122 relative to the temperature of the switching element 121. The horizontal axis of the graph illustrated in FIG. 2 indicates the temperature of the switching element 121. The vertical axis of the graph illustrated in FIG. 2 indicates the forward voltage VF of the temperature detection section 122.

As illustrated in FIG. 2, the temperature detection section 122 has a temperature characteristic in which the forward voltage VF decreases with an increase in the temperature of the switching element 121. The temperature detection section 122 sets the forward voltage VF, which varies according to the temperature of the switching element 121, as the detection temperature, and outputs a temperature detection signal St based on the detection temperature to the control circuit 11A. The relation between the forward voltage VF and the temperature detection signal St of the temperature detection section 122 is described below.

FIG. 3 is a view schematically illustrating a cross-section of the semiconductor device 1A. For ease of understanding, FIG. 3 does not illustrate bonding wires or a lead frame connecting the control circuit 11A and the semiconductor element 12 to each other and conductive patterns electrically connected to the control circuit 11A and the semiconductor element 12. The shapes, sizes, and arrangement, for example, of the control circuit 11A and the semiconductor element 12 illustrated in FIG. 3 are different from the actual shapes, sizes, and arrangement, for example.

As illustrated in FIG. 3, the semiconductor device 1A includes an insulating substrate 31, a resin case 32, a semiconductor chip substrate 33, a circuit board 34, an integrated circuit board 35, and a base part 36. The temperature detection section 122 (not illustrated in FIG. 3) may be provided in any of the semiconductor chip substrate 33 where the semiconductor element 12 is formed, the insulating substrate 31 where the semiconductor element 12 is mounted, the circuit board 34 where the control circuit 11A is mounted, the inside 321 of the resin case 32 where the semiconductor element 12 and the control circuit 11A are housed, or the outside 322 of the resin case 32 in contact with the resin case 32. The semiconductor element 12 is mounted on the insulating substrate 31 by the semiconductor chip substrate 33 being mounted on the insulating substrate 31, for example. The control circuit 11A is formed in the integrated circuit board 35, for example, and is mounted on the circuit board 34 by the integrated circuit board 35 being mounted on the circuit board 34. The insulating substrate 31, the circuit board 34, and the resin case 32 are arranged on the base part 36. Space formed by the resin case 32 and the base part 36 is the inside 321 of the resin case 32. The temperature detection section 122 is desirably arranged close to the switching element 121 to detect the temperature of the switching element 121 with high accuracy.

Returning to FIG. 1, the control circuit 11A has a signal generation section 111, an overcurrent detection section 112A, an overheat detection section 113, and a gate drive circuit 114.

The signal generation section 111 has a first reference signal generation section 111a and a temperature variable signal generation section 111b. The signal generation section 111 generates a temperature variable signal Stv varying according to a detection temperature detected by the temperature detection section 122 using the temperature detection signal St having information on the detection temperature.

The first reference signal generation section 111a generates a first reference signal Sr1 having a temperature-independent voltage. The first reference signal generation section 111a contains a bandgap reference (BGR) circuit, for example. This allows the first reference signal generation section 111a to generate a first reference signal Sr1 having an absolute reference voltage independent of the supply voltage input into the control circuit 11A, the temperature of the control circuit 11A, and a process of the control circuit 11A.

The temperature variable signal generation section 111b generates the temperature variable signal Stv based on a difference between the first reference signal Sr1 output from the first reference signal generation section 111a and the temperature detection signal St. The temperature variable signal generation section 111b has a differential circuit 111b-1 generating a differential signal Sdf between the first reference signal Sr1 and the temperature detection signal St and a level change circuit 111b-2 changing the signal level of the differential signal Sdf output from the differential circuit 111b-1.

The differential circuit 111b-1 has an operational amplifier. The operational amplifier has an inverting input terminal (−) and a non-inverting input terminal (+) serving as two input terminals of the differential circuit 111b-1. The operational amplifier has an output terminal serving as an output terminal of the differential circuit 111b-1. The differential circuit 111b-1 has an inverting input terminal (−) connected to the temperature detection terminal T4. The differential circuit 111b-1 has a non-inverting input terminal (+) connected to an output terminal of the first reference signal generation section 111a. The output terminal of the differential circuit 111b-1 is connected to an input terminal of the level change circuit 111b-2. This allows the differential circuit 111b-1 to output the differential signal Sdf obtained by subtracting the temperature detection signal St from the first reference signal Sr1 to the level change circuit 111b-2.

The level change circuit 111b-2 contains an adder circuit, for example. The level change circuit 111b-2 changes the signal level of the differential signal Sdf to be higher by adding a temperature-independent signal having a constant signal level (i.e., voltage level) to the differential signal Sdf input from the differential circuit 111b-1. The constant signal is generated by the BGR circuit (not illustrated), for example. The temperature variable signal generation section 111boutputs the differential signal Sdf, in which the signal level has been level-shifted in the level change circuit 111b-2, as the temperature variable signal Stv. Both the first reference signal Sr1 and the constant signal added in the level change circuit 111b-2 are temperature-independent signals. Therefore, the differential signal Sdf and the temperature variable signal Stv obtained by converting the signal level of the differential signal Sdf become signals having only information on the temperature of the switching element 121.

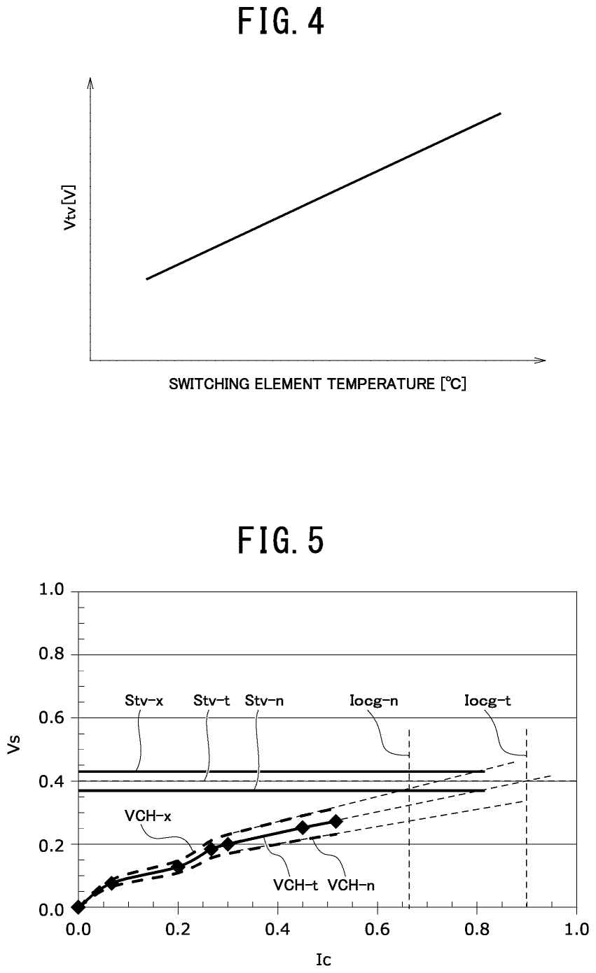

FIG. 4 is a view schematically illustrating one example of the temperature characteristic of a voltage level Vtv of the temperature variable signal Stv relative to the temperature of the switching element 121. The horizontal axis of the graph illustrated in FIG. 4 indicates the temperature of the switching element 121. The vertical axis of the graph illustrated in FIG. 4 indicates the voltage level Vtv of the temperature variable signal Stv.

The temperature variable signal Stv becomes the signal having only information on the temperature of the switching element 121, and therefore the voltage level Vtv of the temperature variable signal Stv has the characteristic of increasing with a decrease in the forward voltage VF (see FIG. 2) of the temperature detection section 122 due to an increase in the temperature of the switching element 121 as illustrated in FIG. 4. The absolute value of the increase rate of the voltage level Vtv of the temperature variable signal Stv relative to temperature variations in the switching element 121 is substantially equal to the absolute value of the decrease rate of the forward voltage VF of the temperature detection section 122 relative to the temperature variations in the switching element 121.

Returning to FIG. 1, the overcurrent detection section 112A has a current detection signal generation circuit 112c, a comparator 112d, and a filter circuit 112e. The overcurrent detection section 112A detects that a current flowing into the switching element 121 is an overcurrent using a current detection signal Ss having information on the detection current Is detected by the current detection section 121a and the temperature variable signal Stv output from the signal generation section 111.

The current detection signal generation circuit 112c generates the current detection signal Ss of a voltage based on the detection current Is. The current detection signal generation circuit 112c has a resistive element R. The resistive element R is provided between the overcurrent detection terminal T3 and a reference potential part of the control circuit 11A. The current detection signal generation circuit 112c generates the current detection signal Ss with a voltage, which is generated between both terminals of the resistive element R by the detection current Is flowing into the resistive element R, as a signal level.

The comparator 112d compares the temperature variable signal Stv with the current detection signal Ss. The comparator 112d has a non-inverting input terminal (+) connected to an output terminal of the signal generation section 111, i.e., an output terminal of the temperature variable signal generation section 111b. The comparator 112d has an inverting input terminal (−) connected to the overcurrent detection terminal T3 and one terminal of the resistive element R. The other terminal of the resistive element R is connected to the reference potential part of the control circuit 11A. Therefore, into the non-inverting input terminal (+) of the comparator 112d, the temperature variable signal Stv serving as a reference signal for determining whether the current flowing into the switching element 121 is an overcurrent, is input. Into the inverting input terminal (−) of the comparator 112d, the current detection signal Ss is input, which has information (i.e., current value) on the detection current Is proportional to the collector current Ic flowing into the switching element 121.

When the signal level of the current detection signal Ss is lower than the signal level of the temperature variable signal Stv, the comparator 112d outputs a comparison signal Sc having a high signal level. On the other hand, when the signal level of the current detection signal Ss is higher than the signal level of the temperature variable signal Stv, the comparator 112d outputs a comparison signal Sc having a low signal level. In this embodiment, the signal level of each of the temperature variable signal Stv, the current detection signal Ss, and the comparison signal Sc is a voltage level, for example.

Thus, when the comparator 112d outputs the comparison signal Sc (in this embodiment, the comparison signal Sc having a low signal level) indicating that the signal level of the current detection signal Ss is higher than the signal level of the temperature variable signal Stv, the overcurrent detection section 112A detects that the current flowing into the switching element 121 is an overcurrent.

The input impedance of the inverting input terminal (−) of the comparator 112d is very high as compared with the resistance value of the resistive element R. Therefore, the detection current Is does not almost flow into the comparator 112d side but flows into the resistive element R. Therefore, the voltage generated in the resistive element R has a voltage level corresponding to the current value of the detection current Is. Thus, the signal level of the current detection signal Ss varies dependent on the current amount of the collector current Ic flowing into the switching element 121. As described above, the temperature variable signal Stv has a signal level varying dependent on the temperature of the switching element 121 without depending on the temperature of the control circuit 11A. Therefore, the comparator 112d can determine whether the current flowing into the switching element 121 is an overcurrent considering the temperature of the switching element 121 by comparing the current detection signal Ss with the temperature variable signal Stv.

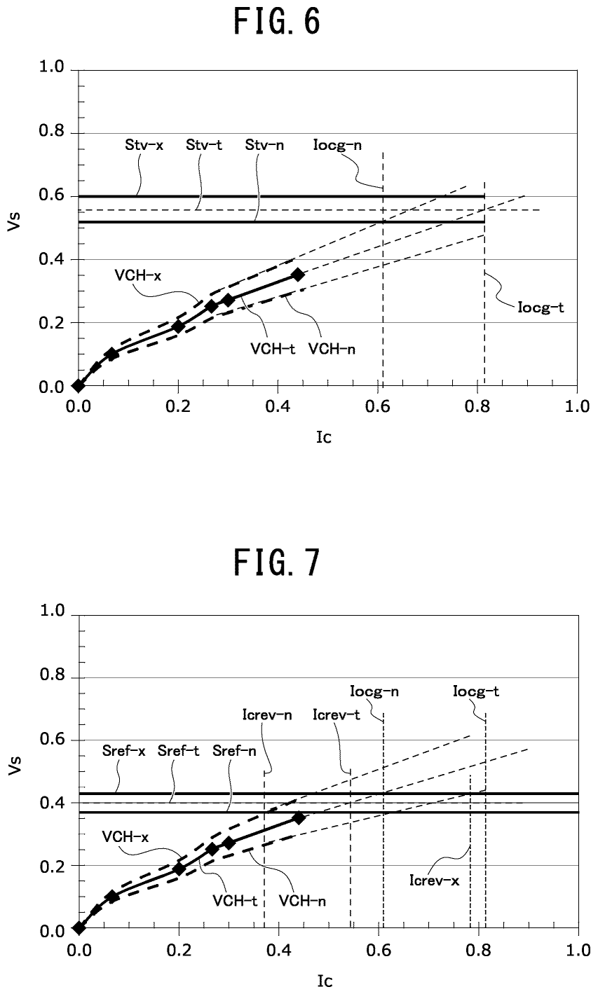

Herein, the relation among the temperature of the switching element 121, the temperature variable signal Stv, and the current detection signal Ss is described using FIGS. 5 and 6. FIG. 5 is a graph showing one example of the characteristic of the signal level of the current detection signal relative to the collector current Ic when the temperature of the switching element 121 is normal temperature (e.g., the temperature when the switching element 121 starts to operate). FIG. 6 is a graph showing one example of the characteristic of the signal level of the current detection signal relative to the collector current Ic at a predetermined temperature at which the temperature of the switching element 121 is higher than normal temperature.

The horizontal axis of each of the graphs illustrated in FIGS. 5 and 6 indicates the collector current Ic flowing into the switching element 121. The vertical axis of each of the graphs illustrated in FIGS. 5 and 6 indicates the signal level of the current detection signal by the voltage level. The horizontal axis of each of the graphs illustrated in FIGS. 5 and 6 indicates the values normalized by the same maximum value. Similarly, the vertical axis of each of the graphs illustrated in FIGS. 5 and 6 indicates values normalized by the same maximum value. Hereinafter, the current detection signal having the signal level indicated by the voltage level is sometimes referred to as a “current detection voltage”.

As illustrated in FIGS. 5 and 6, the current detection voltage Vs is higher the larger the collector current Ic flowing into the switching element 121. The switching element 121 has element variations due to various factors, such as manufacturing variations, which cause variations in the collector current Ic even when the same gate voltage is applied to the gate G. This causes variations also in the detection current Is output from the current detection section 121a provided in the switching element 121, which causes variations also in the current detection voltage Vs. FIGS. 5 and 6 illustrate design characteristics when the current detection voltage Vs varies.

A standard characteristic VCH-t of the current detection voltage Vs shows the characteristic when the collector current Ic having a designed value flows into the switching element 121. The minimum characteristic VCH-n of the current detection voltage Vs shows the characteristic when the minimum collector current Ic in the design range flows into the switching element 121. The maximum characteristic VCH-x of the current detection voltage Vs shows the characteristic when the maximum collector current Ic in the design range flows into the switching element 121.

As shown by the standard characteristic VCH-t, the minimum characteristic VCH-n, and the maximum characteristic VCH-x of the current detection voltage Vs, the variations in the current detection voltage Vs due to the element variations in the switching element 121 are larger the larger the collector current Ic flowing into the switching element 121. As can be seen by comparing the standard characteristic VCH-t, the minimum characteristic VCH-n, and the maximum characteristic VCH-x of the current detection voltage Vs shown in each of FIGS. 5 and 6, when the collector current Ic flowing into the switching element 121 is the same, the current detection voltage Vs is overall higher the higher the temperature of the switching element 121.

The temperature variable signal Stv used as the overcurrent threshold to determine whether the current flowing into the switching element 121 is an overcurrent varies in a predetermined range relative to the design value due to the element variations in the switching element 121 or element variations in electronic components constituting the signal generation section 111 or the like. Therefore, the temperature variable signal Stv varies in the designed range from the minimum value Stv-n to the maximum value Stv-x. A standard value Stv-t shows the value as designed and is the center value of the minimum value Stv-n and the maximum value Stv-x. As illustrated in FIGS. 5 and 6, the range of variations in the temperature variable signal Stv is wider, for example, the higher the temperature of the switching element 121.

The standard value Stv-t of the temperature variable signal Stv is set to intersect the standard characteristic VCH-t of the current detection voltage Vs in the collector current Ic having a current value coinciding with a standard current value Iocg-t of an overcurrent protection current serving as the criterion for determining whether the current flowing into the switching element 121 is an overcurrent. When the current value of the collector current Ic flowing into the switching element 121 is equal to or smaller than the standard current value Iocg-t, the current flowing into the switching element 121 is determined not to be an overcurrent. On the other hand, when the current value of the collector current Ic flowing into the switching element 121 is larger than the standard current value Iocg-t, the current flowing into the switching element 121 is determined to be an overcurrent.

As described above, the signal generation section 111 can change the signal level (i.e., voltage level) of the temperature variable signal Stv according to the temperature of the switching element 121. Therefore, as illustrated in FIG. 6, when the temperature of the switching element 121 is higher than normal temperature, the standard value Stv-t of the temperature variable signal Stv becomes larger. Thus, even when the temperature of the switching element 121 reaches a predetermined temperature higher than normal temperature, and the standard characteristic VCH-t of the current detection voltage Vs shifts to the higher side of the voltage level, the standard value Stv-t of the temperature variable signal Stv intersects the standard characteristic VCH-t of the current detection voltage Vs at the standard current value Iocg-t of the switching element 121 at a predetermined temperature.

The temperature variable signal Stv varies in such a manner that, when the temperature of the switching element 121 increases, the signal level equivalent to the standard value Stv-t increases and, when the temperature of the switching element 121 decreases, the signal level equivalent to the standard value Stv-t decreases. Therefore, as illustrated in FIGS. 5 and 6, the semiconductor device 1A can set the current value of the collector current Ic where the standard value Stv-t of the temperature variable signal Stv intersects the standard characteristic VCH-t of the current detection voltage Vs as the standard current value Iocg-t of the overcurrent protection current irrespective of the temperature of the switching element 121.

This allows the semiconductor device 1A to achieve an increase in the accuracy of the overcurrent detection of the switching element 121 relative to the temperature variations in the switching element 121. The temperature variable signal Stv and the current detection voltage Vs each vary in a predetermined design range. Therefore, there is a possibility that the current value of the collector current Ic where the temperature variable signal Stv and the temperature characteristic of the current detection voltage Vs intersect each other also varies. Thus, in the design of the semiconductor device 1A, a tolerance is set for the variations of the current value of the collector current Ic at the intersection where the temperature variable signal Stv and the temperature characteristic of the current detection voltage Vs intersect each other. In the semiconductor device 1A, the range from the minimum current value Iocg-n to the maximum current value (not illustrated) of the overcurrent protection current, for example, is set as the tolerance. Even when the collector current Ic at the intersection varies in the range from the minimum current value Iocg-n to the relevant maximum current value, the detection accuracy of the overcurrent of the switching element 121 in the semiconductor device 1A does not deteriorate.

The comparator 112d has an output terminal to which an input terminal of the filter circuit 112e is connected. The filter circuit 112e outputs the overcurrent protection signal Soc when the signal level of the comparison signal Sc output from the comparator 112d is kept at the low level even after the passage of a predetermined time (e.g., 4 μs) after the signal level of the comparison signal Sc output from the comparator 112d has varied from the high level to the low level. The filter circuit 112e is a delay circuit delaying the comparison signal Sc input from the comparator 112d by a predetermined time. The overcurrent detection section 112A includes the filter circuit 112e on the output side, and thus can suppress the output of the overcurrent protection signal Soc based on a malfunction of the comparator 112d due to noise or the like.

As illustrated in FIG. 1, the overheat detection section 113 has a constant current source 113a, a comparator 113b, and a reference signal generation section 113c. The overheat detection section 113 detects the temperature of the switching element 121 and, when the detected temperature exceeds the rated temperature, outputs the overheat protection signal Soh.

The constant current source 113a is provided among an output terminal to which the supply voltage serving as the power supply of the control circuit 11A is output, the temperature detection terminal T4, an inverting input terminal (−) of the comparator 113b, and the inverting input terminal (−) of the differential circuit 111b-1 provided in the signal generation section 111. The constant current source 113a outputs a constant current having a predetermined current value toward the temperature detection terminal T4, comparator 113b, and differential circuit 111b-1 sides. The input impedance of the inverting input terminal (−) of each of the comparator 113b and the operational amplifier constituting the differential circuit 111b-1 is very high as compared with the resistance value of the forward resistance of the temperature detection section 122. Therefore, the constant current output from the constant current source 113a does not almost flow into the comparator 113b and differential circuit 111b-1 sides but flows into the temperature detection section 122.

The temperature detection section 122 has a characteristic in which the resistivity varies according to the temperature, and therefore, when the temperature of the temperature detection section 122 increases with an increase in the temperature of the switching element 121, the forward resistance decreases. Therefore, the forward voltage VF of the temperature detection section 122 is lower the higher the temperature of the switching element 121 and is higher the lower the temperature of the switching element 121. Thus, the forward voltage VF of the temperature detection section 122, i.e., voltage in the temperature detection terminal T4, varies according to the temperature of the switching element 121. Then, the overheat detection section 113 inputs the voltage in the temperature detection terminal T4 with the variations in the forward voltage VF of the temperature detection section 122 as the signal level of the temperature detection signal St into the inverting input terminal (−) of the comparator 113b. Thus, the temperature detection signal St becomes the signal having the information on the detection temperature detected by the temperature detection section 122 as the signal level.

As described above, the temperature detection terminal T4 is connected to the inverting input terminal (−) of the differential circuit 111b-1 provided in the temperature variable signal generation section 111b of the signal generation section 111. Therefore, into the inverting input terminal (−) of the differential circuit 111b-1, the temperature detection signal St is input, which has the information on the detection temperature detected by the temperature detection section 122 (i.e., temperature information of the switching element 121) as the signal level.

To a non-inverting input terminal (+) of the comparator 113b, the reference signal generation section 113c is connected. The reference signal generation section 113c contains a direct-current power supply, for example. The positive electrode side of the reference signal generation section 113c is connected to the non-inverting input terminal (+) of the comparator 113b. The negative electrode side of the reference signal generation section 113c is connected to a reference potential part of the control circuit 11A.

Into the non-inverting input terminal (+) of the comparator 113b, a reference signal Sr generated by the reference signal generation section 113c is input. The reference signal Sr has a constant signal level (i.e., constant voltage level). On the other hand, the temperature detection signal St having a signal level (i.e., voltage level) reflecting the temperature of the switching element 121 is input into the inverting input terminal (−) of the comparator 113b.

The comparator 113b outputs a comparison signal having a high signal level as the overheat protection signal Soh when the signal level of the temperature detection signal St is lower than the signal level of the reference signal Sr. On the other hand, the comparator 113b outputs a comparison signal having a low signal level as the overheat protection signal Soh when the signal level of the temperature detection signal St is higher than the signal level of the reference signal Sr. In this embodiment, the signal level of each of the reference signal Sr, the temperature detection signal St, and the overheat protection signal Soh is the voltage level, for example.

The overheat detection section 113 detects that the switching element 121 is overheated when the signal level of the temperature detection signal St is higher than the signal level of the reference signal Sr, and outputs a comparison signal having a low signal level as the overheat protection signal Soh to the comparator 113b. Thus, the overheat detection section 113 reports that the switching element 121 is overheated by changing the signal level of the overheat protection signal Soh.

The gate drive circuit 114 generates a gate signal for controlling the switching element 121 based on a pulsed input signal (not illustrated) input from the outside of the control circuit 11A. The gate drive circuit 114 has an output terminal connected to the gate signal output terminal T1. When the switching element 121 is to be turned on, the gate drive circuit 114 outputs a gate signal from the gate signal output terminal T1 to the gate G of the switching element 121. Therefore, the gate signal is input (i.e., a gate current is supplied) into the gate G of the switching element 121 from the gate drive circuit 114, so that the gate capacitance (not illustrated) is charged. Thus, the gate voltage of the gate G increases to a high level, so that the switching element 121 is turned on.

When the switching element 121 is to be turned off, the gate drive circuit 114 does not output a gate signal to the gate G of the switching element 121 from the gate signal output terminal Tl and short-circuits, for example, the gate G and the reference potential part of the control circuit 11A. This discharges the electric charge charged in the gate capacitance of the switching element 121, and therefore the gate voltage of the gate G decreases to a low level, so that the switching element 121 is turned off.

Thus, the control circuit 11A drives the switching element 121 by the gate drive circuit 114 and protects the switching element 121 by the overcurrent detection section 112A and the overheat detection section 113. The control circuit 11A is integrally formed on, for example, an integrated circuit board 35 (see FIG. 3) and functions as an integrated circuit for driving/protecting the switching element 121.

### 1-2. Operation of Semiconductor Device

One example of an overcurrent detection operation of the semiconductor device 1A according to this embodiment is described using FIGS. 1, 5, and 6 again.

The turn-on of the switching element 121 (see FIG. 1) by the gate drive circuit 114 causes the collector current Ic to flow into the switching element 121. The flow of the collector current Ic into the switching element 121 results in the input of the detection current Is into the current detection signal generation circuit 112c (see FIG. 1) via the overcurrent detection terminal T3 from the current detection section 121a. The current detection signal generation circuit 112c generates the current detection signal Ss using the detection current Is input from the current detection section 121a and outputs the current detection signal Ss to the inverting input terminal (−) of the comparator 112d.

When the temperature of the switching element 121 is, for example, normal temperature, the temperature variable signal Stv having a signal level corresponding to normal temperature is input into the non-inverting input terminal (+) of the comparator 112d from the signal generation section 111 (see FIG. 1), and the current detection signal Ss is input into the inverting input terminal (−) of the comparator 112d from the current detection signal generation circuit 112c. The temperature variable signal Stv input into the non-inverting input terminal (+) of the comparator 112d varies in the range from the minimum value Stv-n to the maximum value Stv-x illustrated in FIG. 5, for example. The signal level (i.e., voltage level) of the current detection signal Ss input into the inverting input terminal (−) of the comparator 112d varies in the range from the minimum characteristic VCH-n to the maximum characteristic (not illustrated) of the current detection voltage Vs illustrated in FIG. 5, for example.

The comparator 112d compares the signal level of the temperature variable signal Stv to be input with the signal level of the current detection signal Ss. When the comparator 112d has determined that the signal level of the current detection signal Ss is equal to or lower than the signal level of the temperature variable signal Stv, the comparator 112d outputs the comparison signal Sc having a high signal level indicating that no overcurrent is generated to the filter circuit 112e (see FIG. 1). Thus, the overcurrent detection section 112A does not output the overcurrent protection signal Soc (see FIG. 1).

On the other hand, when the comparator 112d has determined that the signal level of the current detection signal Ss is higher than the signal level of the temperature variable signal Stv, the comparator 112d outputs the comparison signal Sc having a low signal level indicating that an overcurrent is generated to the filter circuit 112e. When the comparator 112d has continuously output the comparison signal Sc having a low signal level for a predetermined time (e.g., 4 μs), the overcurrent detection section 112A outputs the overcurrent protection signal Soc.

It is assumed that the temperature has increased due to the continuous operation of the switching element 121. Then, the signal level of the current detection signal Ss output from the current detection signal generation circuit 112c is higher than that in the case of normal temperature. The signal level of the temperature variable signal Stv output from the signal generation section 111 increases with an increase in the temperature of the switching element 121 irrespective of the temperature of the control circuit 11A.

When the temperature of the switching element 121 increases and the current detection voltage Vs has the temperature characteristic illustrated in FIG. 6, for example, the temperature variable signal Stv illustrated in FIG. 6, for example, is input into the non-inverting input terminal (+) of the comparator 112d from the signal generation section 111, and the current detection signal Ss having the voltage level of the current detection voltage Vs illustrated in FIG. 6 as the signal level is input into the inverting input terminal (−) of the comparator 112d from the current detection signal generation circuit 112c. The temperature variable signal Stv input into the non-inverting input terminal (+) of the comparator 112d varies in the range from the minimum value Stv-n to the maximum value Stv-x illustrated in FIG. 6, for example. The signal level (i.e., voltage level) of the current detection signal Ss input into the inverting input terminal (−) of the comparator 112d varies in the range from the minimum characteristic VCH-n to the maximum characteristic (not illustrated) of the current detection voltage Vs illustrated in FIG. 6, for example.

The comparator 112d compares the signal level of the temperature variable signal Stv to be input with the signal level of the current detection signal Ss. When the comparator 112d has determined that the signal level of the current detection signal Ss is equal to or lower than the signal level of the temperature variable signal Stv, the comparator 112d outputs the comparison signal Sc having a high signal level indicating that no overcurrent is generated to the filter circuit 112e. Thus, the overcurrent detection section 112A does not output the overcurrent protection signal Soc.

On the other hand, when the comparator 112d has determined that the signal level of the current detection signal Ss is higher than the signal level of the temperature variable signal Stv, the comparator 112d outputs the comparison signal Sc having a low signal level indicating that an overcurrent is generated to the filter circuit 112e. When the comparator 112d has continuously output the comparison signal Sc having a low signal level for a predetermined time (e.g., 4 μs), the overcurrent detection section 112A outputs the overcurrent protection signal Soc.

Thus, the semiconductor device 1A can set the signal level of the temperature variable signal Stv dependent on the temperature of the switching element 121 irrespective of the temperature of the control circuit 11A, even when the temperature of the control circuit 11A is the same as or different from the temperature of the switching element 121. This allows the semiconductor device 1A to enhance the detection accuracy of the overcurrent of the switching element 121 even when the temperatures of the control circuit 11A and the switching element 121 are different from each other.

### 1-3. Advantageous Effects of Semiconductor Device

The advantageous effects of the semiconductor device 1A according to this embodiment are described using FIG. 7 referring to FIGS. 1, 5, and 6. First, in describing the advantageous effects of the semiconductor device 1A, problems of the IPM as a conventional semiconductor device are described.

In the conventional IPM, a current flowing into a switching element is detected based on a detection current flowing into a current detection section provided in the switching element as with the semiconductor device 1A. A current detection voltage based on the detection current has temperature dependency and is higher the higher the temperature of the switching element (see FIGS. 5 and 6). In the conventional IPM, a temperature characteristic is imparted to a reference signal (equivalent to the temperature variable signal Stv in this embodiment) to be input into a comparator for overcurrent detection, assuming the temperature characteristic of the switching element. More specifically, in the conventional IPM, a plurality of reference signals is prepared which has signal levels corresponding to the temperature of the switching element and different from each other. Further, the conventional IPM has a detection circuit for detecting the temperature of a control circuit controlling the switching element. Thus, even when the temperature of the switching element varies and the characteristic of the current detection voltage relative to a collector current varies, the threshold for overcurrent detection (equivalent to the overcurrent threshold in this embodiment) is set as designed. However, in the conventional IPM, the temperature characteristic is imparted to the reference signal for overcurrent detection, assuming that the temperatures of the switching element and the control circuit controlling the switching element are the same or fall within a predetermined range. More specifically, in the conventional IPM, the signal level of the reference signal is set according to the temperature of the control circuit.

Therefore, even when the switching element generates heat, for example, as a result of its operation, so that the temperature of the switching element increases to a temperature higher than normal temperature, the temperature of the control circuit sometimes is maintained at a temperature equal to normal temperature, for example. In this case, even when the current detection voltage Vs relative to the collector current Ic is overall higher than that at normal temperature (see FIG. 5) as illustrated in FIG. 7, the standard value Sref-t of a reference signal Sref is set to a value used at normal temperature. Thus, the current detection voltage Vs is higher than the standard value Sref-t of the reference signal Sref at a standard current value Icrev-t of the collector current Ic flowing into the switching element. The standard current value Icrev-t of the collector current Ic is smaller than a standard current value Iocgn-t of the overcurrent protection current. As a result, the conventional IPM erroneously detects that the current flowing into the switching element is an overcurrent, even when the collector current Ic (i.e., overcurrent) equivalent to the overcurrent protection current does not flow into the switching element.

In the conventional IPM, each of the reference signal Sref and the current detection voltage Vs varies in a predetermined design range. Therefore, there is a possibility that the current value of the collector current Ic where the reference signal Sref and the temperature characteristic of the current detection voltage Vs intersect each other also varies. More specifically, there is a possibility that the current value where the reference signal Sref and the current detection voltage Vs intersect each other varies in the range from the minimum current value Icrev-n to the maximum current value Icrev-x. However, the range from the minimum current value Icrev-n to the maximum current value Icrev-x lies in a region where the collector current Ic is smaller than that in the range from the minimum current value Icong-n to the maximum current value (not illustrated) of the overcurrent protection current. Therefore, the conventional IPM erroneously detects the current flowing into the switching element as an overcurrent, even when the current value of the collector current Ic where the reference signal Sref and the temperature characteristic of the current detection voltage Vs intersect each other varies.

Thus, although the conventional IPM can detect an overcurrent in the switching element considering the temperatures of the control circuit and the switching element, there is a possibility that the detection accuracy of overcurrent detection decreases when the temperature of the control circuit and the temperature of the IGBT are different from each other. Thus, the conventional IPM has such a problem that the function of protecting the switching element deteriorates.

In contrast thereto, in the semiconductor device 1A in this embodiment, the temperature variable signal Stv depends on the temperature of the switching element 121, whereas the temperature variable signal Stv does not depend on the temperature of the control circuit 11A. Therefore, in the semiconductor device 1A, the temperature variable signal Stv varies according to variations in the temperature of the switching element 121 and does not vary even when the temperature of the control circuit 11A varies. This allows the semiconductor device 1A to compare the temperature variable signal Stv corresponding to the temperature of the switching element 121 with the current detection voltage Vs based on the detection current Is, even when the temperature of the control circuit 11A and the temperature of the switching element 121 are different from each other. Therefore, the semiconductor device 1A can enhance the detection accuracy of the overcurrent of the switching element 121 and prevent the deterioration of the function of protecting of the switching element 121. Further, the semiconductor device 1A does not need to detect the temperature of the control circuit 11A and does not need a circuit detecting the temperature of the control circuit 11A. This allows the semiconductor device 1A to simplify, downsize, and reduce the cost of the circuit configuration of the control circuit 11A.

As described above, the semiconductor device 1A according to this embodiment includes: the semiconductor element 12 having the switching element 121, the temperature detection section 122 configured to detect the temperature of the switching element 121, and the current detection section 121a configured to detect a current of the switching element 121; and the control circuit 11A configured to control the semiconductor element 12, in which the control circuit 11A has the signal generation section 111 configured to generate the temperature variable signal Stv varying according to the detection temperature detected by the temperature detection section 122 using the temperature detection signal St having information on the detection temperature, and the overcurrent detection section 112A configured to detect that the current flowing into the switching element 121 is an overcurrent using the current detection signal Ss having information on the detection current Is detected by the current detection section 121a and the temperature variable signal Stv output from the signal generation section 111.

The semiconductor device 1A having such a configuration can prevent the deterioration of the function of protecting of the switching element 121 even when the temperatures of the switching element 121 to be protected and the control circuit 11A controlling switching element 121 are different from each other.

### Second Embodiment

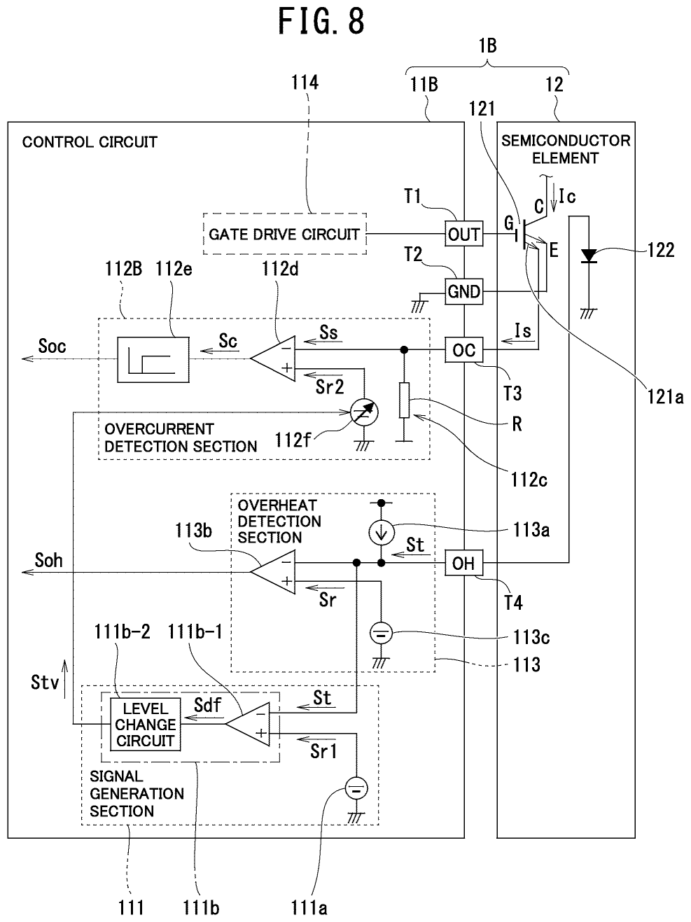

A semiconductor device according to a second embodiment of the present invention is described using FIG. 8. The semiconductor device according to this embodiment has a feature of detecting whether a current flowing into a switching element is an overcurrent by comparing a second reference signal generated by a second reference signal generation circuit controlled by a temperature variable signal with a current detection signal.

### 2-1. Schematic Configuration of Semiconductor Device

The schematic configuration of a semiconductor device 1B according to this embodiment is described using FIG. 8. FIG. 8 is a block diagram illustrating one example of the schematic configuration of the semiconductor device 1B according to this embodiment. For constituent components of the semiconductor device 1B, the constituent components exhibiting the same actions and functions as those of the semiconductor device 1A according to the first embodiment above are marked with the same reference signs, and the descriptions of the constituent components are omitted unless necessary.

As illustrated in FIG. 8, the semiconductor device 1B according to this embodiment includes the semiconductor element 12 having the switching element 121, the temperature detection section 122 detecting the temperature of the switching element 121, and the current detection section 121a detecting a current of the switching element 121, and a control circuit 11B controlling the semiconductor element 12. The control circuit 11B has the signal generation section 111 generating the temperature variable signal Stv varying according to the detection temperature detected by the temperature detection section 122 using the temperature detection signal St having information on the detection temperature. The control circuit 11B also has an overcurrent detection section 112B detecting that a current flowing into the switching element 121 is an overcurrent using the current detection signal Ss having information on the detection current Is detected by the current detection section 121a and the temperature variable signal Stv output from the signal generation section 111.

The overcurrent detection section 112B has the current detection signal generation circuit 112c, the comparator 112d, the filter circuit 112e, and a second reference signal generation circuit 112f. The second reference signal generation circuit 112f generates a second reference signal Sr2 having a signal level varying according to the signal level of the temperature variable signal Stv. The comparator 112d compares the second reference signal Sr2 output from the second reference signal generation circuit 112f with the current detection signal Ss.

The second reference signal generation circuit 112f has, for example, a variable constant current source containing an operational amplifier (not illustrated) and a transistor (not illustrated) and a conversion circuit converting a current output from the variable constant current source into a voltage. The variable constant current source outputs a constant current having a larger current amount the higher the signal level of the temperature variable signal Stv. The conversion circuit outputs a constant voltage having a higher voltage level (i.e., signal having a high signal level) when the current amount of the current output from the variable constant current source is larger. The second reference signal generation circuit 112f outputs the signal output from the conversion circuit as the second reference signal Sr2 to the non-inverting input terminal (+) of the comparator 112d.

The signal level of the second reference signal Sr2 output from the second reference signal generation circuit 112f increases/decreases according to an increase/a decrease in the signal level of the temperature variable signal Stv. Therefore, the second reference signal generation circuit 112f is configured by adjusting the signal level of the second reference signal Sr2 as appropriate considering the temperature characteristic of the switching element 121. For example, the signal level of the second reference signal Sr2 is adjusted to be substantially the same as the signal level of the reference signal Sr in the first embodiment above relative to the temperature of the switching element 121. This allows the comparator 112d in this embodiment to operate in the same manner as the comparator 112d in the first embodiment above. As a result, the overcurrent detection section 112B can operate in the same manner as the overcurrent detection section 112A in the first embodiment above.

Therefore, when the comparator 112d outputs the comparison signal Sc indicating that the current detection signal Ss has a signal level higher than that of the second reference signal Sr2, the overcurrent detection section 112B detects that the current flowing into the switching element 121 is an overcurrent.

### 2-2. Operation of Semiconductor Device

In the semiconductor device 1B according to this embodiment, although the configuration of the overcurrent detection section 112B is different from the configuration of the overcurrent detection section 112A in the first embodiment above, the overcurrent detection operation of the semiconductor device 1B is the same as that of the semiconductor device 1A according to the first embodiment above. Therefore, the description of the operation of the semiconductor device 1B is omitted.

### 2-3. Advantageous Effects of Semiconductor Device

The semiconductor device 1B according to this embodiment includes the signal generation section 111 having the same configuration as that of the signal generation section 111 in the first embodiment above. This allows the semiconductor device 1B to compare the voltage corresponding to the pre-set overcurrent protection current with the current detection voltage Vs based on the detection current Is, even when the temperature of the control circuit 11B and the temperature of the switching element 121 are different from each other, as with the semiconductor device 1A according to the first embodiment above. As a result, the semiconductor device 1B can achieve the enhancement of the detection accuracy of the overcurrent of the switching element 121.

As described above, the semiconductor device 1B according to this embodiment includes: the semiconductor element 12 having the switching element 121, the temperature detection section 122 configured to detect the temperature of the switching element 121, and the current detection section 121a configured to detect a current of the switching element 121; and the control circuit 11B configured to control the semiconductor element 12, in which the control circuit 11B has the signal generation section 111 configured to generate the temperature variable signal Stv varying according to the detection temperature detected by the temperature detection section 122 using the temperature detection signal St having information on the detection temperature, and the overcurrent detection section 112B configured to detect that the current flowing into the switching element 121 is an overcurrent using the current detection signal Ss having information on the detection current Is detected by the current detection section 121a and the temperature variable signal Stv output from the signal generation section 111.

The semiconductor device 1B having such a configuration can prevent the deterioration of the function of protecting of the switching element 121, even when the temperatures of the switching element 121 to be protected and the control circuit 11B controlling switching element 121 are different from each other.

The present invention can be variously modified without being limited to the above-described embodiments.

In the semiconductor device 1A according to the first embodiment and the semiconductor device 1B according to the second embodiment above, the switching element is the insulated gate bipolar transistor, for example, but the present invention is not limited thereto. For example, the switching element may be an insulated gate bipolar transistor or a metal-oxide-semiconductor field-effect transistor.

In the semiconductor device 1A according to the first embodiment above and the semiconductor device 1B according to the second embodiment above, the overheat detection section 113 is configured to output the comparison signal output from the comparator 113b as the overheat protection signal Soh, but the present invention is not limited thereto. For example, the overheat detection section 113 may have a filter circuit as a delay circuit acting in the same manner as the filter circuit 112e on the output side of the comparator 113b. This allows the semiconductor devices to suppress the erroneous detection in the overheat detection section.

In the semiconductor device 1B according to the second embodiment above, the temperature variable signal generation section 111b of the signal generation section 111 has the level change circuit 111b-2 but the present invention is not limited thereto. For example, it may be acceptable that the level change circuit 111b-2 is not provided and the temperature variable signal generation section 111b outputs the differential signal Sdf output from the differential circuit 111b-1 as the temperature variable signal Stv to the second reference signal generation circuit 112f provided in the overcurrent detection section 112B. In this case, the signal level of the temperature variable signal Stv input into the second reference signal generation circuit 112f is different from the signal level of the temperature variable signal Stv in the second embodiment above. However, the second reference signal generation circuit 112f can generate the second reference signal Sr2 having a signal level corresponding to the signal level of the temperature variable signal Stv by adjusting as appropriate or changing as appropriate constituent parts.

The semiconductor device 1A according to the first embodiment above and the semiconductor device 1B according to the second embodiment above are configured to input the temperature detection signal St into the differential circuit 111b-1 provided in the signal generation section 111 but the present invention is not limited thereto. For example, the signal generation section 111 may be configured so that the differential circuit 111b-1 is not provided and the temperature detection signal St is directly input into the level change circuit 111b-2. In this case, the signal generation section 111 may output the temperature detection signal St, in which the signal level has been changed to a signal level applicable to the comparator 112d provided in the overcurrent detection section 112A in the level change circuit 111b-2, as the temperature variable signal Stv to the comparator 112d provided in the overcurrent detection section 112A. For example, the signal generation section 111 may also output the temperature detection signal St, in which the signal level has been changed to a signal level capable of controlling the second reference signal generation circuit 112f, as the temperature variable signal Stv to the second reference signal generation circuit 112f provided in the overcurrent detection section 112A.

For example, it may also be acceptable that the signal generation section 111 is not provided and the temperature detection signal St is input as the temperature variable signal Stv into the comparator 112d provided in the overcurrent detection section 112A. Furthermore, for example, it may be acceptable that the signal generation section 111 is not provided and the second reference signal generation circuit 112f provided in the overcurrent detection section 112A is controlled with the temperature detection signal St as the temperature variable signal Stv. In these cases, the resistance value of the resistive element R provided in the current detection signal generation circuit 112c of the overcurrent detection section 112A needs to be adjusted as appropriate such that the comparators 112d provided in the overcurrent detection sections 112A, 112B can compare the temperature variable signal Stv or the second reference signal Sr2 with the current detection signal Ss.

Also when semiconductor devices have any of these configurations, advantageous effects similar to the advantageous effects obtained by the semiconductor device 1A according to the first embodiment above and the semiconductor device 1B according to the second embodiment above can be obtained.

The technical scope of the present invention is not limited to the illustrated and described exemplary embodiments and also includes all embodiments producing advantageous effects equivalent to the advantageous effects targeted by the present invention. Further, the technical scope of the present invention is not limited to combinations of the features of the invention defined by each claim and can be defined by any desired combination of specific features of all the disclosed features.

### REFERENCE SIGNS LIST

1A, 1B: semiconductor device
11A, 11B: control circuit
12: semiconductor element
31: insulating substrate
32: resin case
33: semiconductor chip substrate
34: circuit board
35: integrated circuit board
36: base part
111: signal generation section
111a: first reference signal generation section
111b: temperature variable signal generation section
111b-1: differential circuit
111b-2: level change circuit
112A, 112B: overcurrent detection section
112c: current detection signal generation circuit
112d, 113b: comparator
112e: filter circuit
112f: second reference signal generation circuit
113: overheat detection section
113a: constant current source
113c: reference signal generation section
114: gate drive circuit
121: switching element
121a: current detection section
122: temperature detection section
321: inside
322: outside
Ic: collector current
Iocg-n: minimum current value
Iocg-t: standard current value
Is: detection current
Sc: comparison signal
Sdf: differential signal
Soc: overcurrent protection signal
Soh: overheat protection signal
Sr, Sref: reference signal
Sr1: first reference signal
Sr2: second reference signal
Ss: current detection signal
St: temperature detection signal
Stv: temperature variable signal
Stv-n: minimum value
Stv-t: standard value
Stv-x: maximum value
VCH-n: minimum characteristic
VCH-t: standard characteristic
VCH-x: maximum characteristic
Vs: current detection voltage

1. A semiconductor device comprising:
a semiconductor element having a switching element, a temperature detection section configured to detect a temperature of the switching element, and a current detection section configured to detect a current of the switching element; and
a control circuit configured to control the semiconductor element, wherein
the control circuit has:
a signal generation section configured to generate a temperature variable signal varying according to a detection temperature detected by the temperature detection section using a temperature detection signal having information on the detection temperature; and
an overcurrent detection section configured to detect that a current flowing into the switching element is an overcurrent using a current detection signal having information on a detection current detected by the current detection section and the temperature variable signal output from the signal generation section.

2. The semiconductor device according to claim 1, wherein
the signal generation section has:
a first reference signal generation section configured to generate a first reference signal having a temperature-independent voltage; and
a temperature variable signal generation section configured to generate the temperature variable signal based on a difference between the first reference signal output from the first reference signal generation section and the temperature detection signal.

3. The semiconductor device according to claim 2, wherein
the temperature variable signal generation section has:
a differential circuit configured to generate a differential signal between the first reference signal and the temperature detection signal; and
a level change circuit configured to change a signal level of the differential signal output from the differential circuit.

4. The semiconductor device according to claim 1, wherein the overcurrent detection section has: a comparator configured to compare the temperature variable signal with the current detection signal.

5. The semiconductor device according to claim 4, wherein the overcurrent detection section is configured to detect that an overcurrent flows into the switching element when the comparator outputs a signal indicating that the current detection signal has a signal level higher than a signal level of the temperature variable signal.

6. The semiconductor device according to claim 1, wherein
the overcurrent detection section has:
a second reference signal generation circuit configured to generate a second reference signal having a signal level varying according to a signal level of the temperature variable signal; and
a comparator configured to compare the second reference signal output from the second reference signal generation circuit with the current detection signal.

7. The semiconductor device according to claim 6, wherein the overcurrent detection section is configured to detect that an overcurrent flows into the switching element when the comparator outputs a signal indicating that the current detection signal has a signal level higher than a signal level of the second reference signal.

8. The semiconductor device according to claim 1, wherein
the temperature detection section is provided
in a semiconductor chip substrate where the semiconductor element is formed,
in an insulating substrate where the semiconductor element is mounted,
in a circuit board where the control circuit is mounted,
inside a resin case where the semiconductor element and the control circuit are housed, or
outside the resin case in contact with the resin case.

9. The semiconductor device according to claim 1, wherein the switching element is an insulated gate bipolar transistor or a metal-oxide-semiconductor field-effect transistor.

10. The semiconductor device according to claim 1, wherein the temperature detection section is a temperature-dependent diode.

11. The semiconductor device according to claim 2, wherein the overcurrent detection section has: a comparator configured to compare the temperature variable signal with the current detection signal.

12. The semiconductor device according to claim 11, wherein the overcurrent detection section is configured to detect that an overcurrent flows into the switching element when the comparator outputs a signal indicating that the current detection signal has a signal level higher than a signal level of the temperature variable signal.

13. The semiconductor device according to claim 3, wherein the overcurrent detection section has: a comparator configured to compare the temperature variable signal with the current detection signal.

14. The semiconductor device according to claim 13, wherein the overcurrent detection section is configured to detect that an overcurrent flows into the switching element when the comparator outputs a signal indicating that the current detection signal has a signal level higher than a signal level of the temperature variable signal.

15. The semiconductor device according to claim 2, wherein
the overcurrent detection section has:
a second reference signal generation circuit configured to generate a second reference signal having a signal level varying according to a signal level of the temperature variable signal; and
a comparator configured to compare the second reference signal output from the second reference signal generation circuit with the current detection signal.

16. The semiconductor device according to claim 15, wherein the overcurrent detection section is configured to detect that an overcurrent flows into the switching element when the comparator outputs a signal indicating that the current detection signal has a signal level higher than a signal level of the second reference signal.

17. The semiconductor device according to claim 3, wherein
the overcurrent detection section has:
a second reference signal generation circuit configured to generate a second reference signal having a signal level varying according to a signal level of the temperature variable signal; and
a comparator configured to compare the second reference signal output from the second reference signal generation circuit with the current detection signal.

18. The semiconductor device according to claim 17, wherein the overcurrent detection section is configured to detect that an overcurrent flows into the switching element when the comparator outputs a signal indicating that the current detection signal has a signal level higher than a signal level of the second reference signal.
